(19) United States
(12) Patent Application Publication
(10) Pub. No.: US 2009/0075414 A1
(43) Pub. Date: Mar. 19, 2009

(54) BIOCHIP AND METHOD OF FABRICATION

(75) Inventors: June-Young Lee, Gyeonggi-do (KR); Dong-Ho Lee, Gyeonggi-do (KR); Hyeong-Jun Kim, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/194,459

(22) Filed: Aug. 19, 2008

(30) Foreign Application Priority Data
Sep. 17, 2007 (KR) 2007-0094308

(51) Int. Cl. H01L 21/50

(52) U.S. Cl. 438/49; 257/E21.499

(57) ABSTRACT

A method of fabricating a biochip and a biochip fabricated by the method are provided. The method can include providing a substrate including a plurality of first areas separated from each other by a second area, forming a plurality of activation patterns on each of the first areas, coupling a plurality of probes to each of the activation patterns, and cutting the substrate along the second area to form a plurality of chips.

### CROSS-REFERENCE TO RELATED APPLICATION

This application claims priority from Korean Patent Application No. 10-2007-0094308, filed on Sep. 17, 2007, the disclosure of which is incorporated herein by reference in its entirety.

### BACKGROUND

1. Technical Field

The disclosed technology relates to a method of fabricating a biochip and a biochip fabricated by the method.

2. Description of the Related Art

With the advent of the Human Genome Project, genome nucleotide sequences of a variety of organisms have been identified and attention has been focused on biochips. Biochips have been widely used in gene expression profiling, genotyping through detection of mutation or polymorphism such as Single-Nucleotide Polymorphism (SNP), a protein or peptide assay, potential drug screening, development and preparation of novel drugs, etc.

In conventional methods of fabricating a biochip, multiple biochips are formed on a substrate and the substrate is cut into individual chips by dicing. The dicing is usually performed using a blade dicing process or a laser dicing process in which a laser beam is focused and radiated on the surface of a substrate.

### SUMMARY

The disclosed technology provides a method of fabricating a biochip with improved processing rate and reliability.

The disclosed technology also provides a biochip with improved reliability.

The above and other objects of the disclosed technology will be described in or be apparent from the following description of various embodiments.

Certain embodiments provide a method of fabricating a biochip including providing a substrate having a plurality of first areas separated from each other by a second area; forming a plurality of activation patterns on each of the first areas; coupling a plurality of probes to each of the activation patterns; and cutting the substrate along the second area to form a plurality of chips.

Other embodiments provide a method of fabricating a biochip including providing a substrate having a plurality of first areas separated from each other by a second area, forming an activation layer on each of the first areas, coupling a plurality of probes to the activation layer, and cutting the substrate along the second area to form a plurality of chips.

Further embodiments provide a biochip having an array region, a non-array region surrounding the array region, a substrate, and a probe cell array formed on or in the substrate in the array region, wherein a surface of the substrate is at least partially exposed in the non-array region.

### BRIEF DESCRIPTION OF THE DRAWINGS

The above and other features and advantages of the disclosed technology will become more apparent by describing in detail various embodiments thereof with reference to the attached drawings in which:

FIG. 1 illustrates a layout of a biochip according to certain embodiments of the disclosed technology;

FIGS. 2A through 2C are diagrams for explaining a probe cell array in a biochip, according to certain embodiments of the disclosed technology;

FIGS. 3A through 4 are diagrams for explaining an align key in a biochip, according to certain embodiments of the disclosed technology;

FIG. 5 is a diagram for explaining a probe cell array according to other embodiments of the disclosed technology;

FIGS. 6 through 10C illustrate a method of fabricating a biochip according to certain embodiments of the disclosed technology; and

FIGS. 11A through 14 illustrate a method of fabricating a biochip according to other embodiments of the disclosed technology.

### DETAILED DESCRIPTION

Advantages and features of the disclosed technology and methods of accomplishing the same may be understood more readily by reference to the following detailed description of various embodiments and the accompanying drawings. The disclosed technology may, however, be embodied in many different forms and should not be construed as being limited to the embodiments set forth herein. Rather, these embodiments are provided so that this disclosure will be thorough and complete and will fully convey various concepts of the disclosed technology to those skilled in the art, and the present invention will only be defined by the appended claims. In the drawings, the thickness of layers and regions may be exaggerated for clarity.

It will be understood that when an element such as a layer, region or substrate is referred to as being “on” or extending “onto” another element, it can be directly on or extend directly onto the other element or intervening elements may also be present. In contrast, when an element is referred to as being “directly on” another element, there are no intervening elements present. As used herein the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Like reference numerals refer to like elements throughout the specification.

Hereinafter, it is defined that a vertical direction includes a direction vertical to a surface of the substrate and that a horizontal direction includes a direction horizontal to the surface of the substrate.

The embodiments described in the specification will be described with reference to the plan views and the cross regional views which are illustrative views of the disclosed technology. Accordingly, the illustrative view may be changed as a result of, for example, a manufacturing technique and/or an allowable error. Therefore, the embodiments of the disclosed technology are not limited to the shown specific form, but include the changes of the form produced in accordance with the manufacturing process. Thus, regions shown in the drawings are illustrated in schematic form and the shapes of the regions are presented simply by way of illustration and not as a limitation.

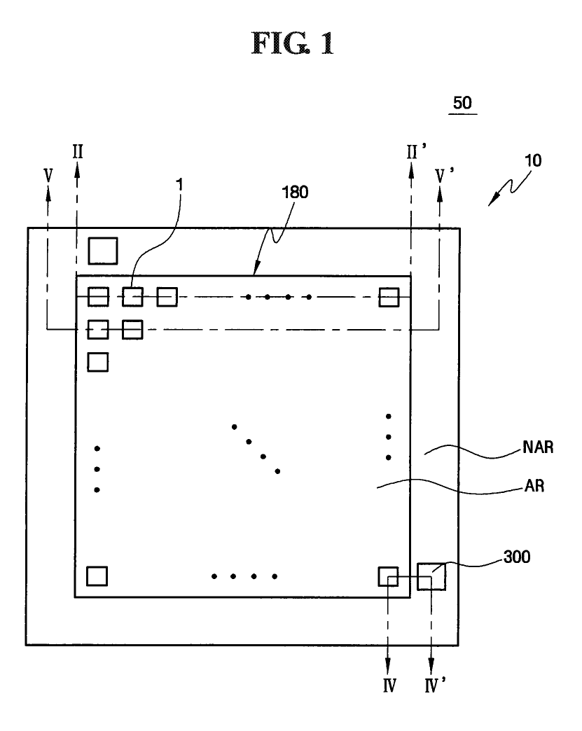

FIG. 1 illustrates a layout of a biochip 50 according to certain embodiments of the disclosed technology. The biochip 50 includes a substrate 10, a probe cell array 180, and an align key 300. In addition, the biochip 50 is divided into an array region AR and a non-array region NAR surrounding the array region AR. The array region AR may be a region in which the probe cell array 180 is formed.

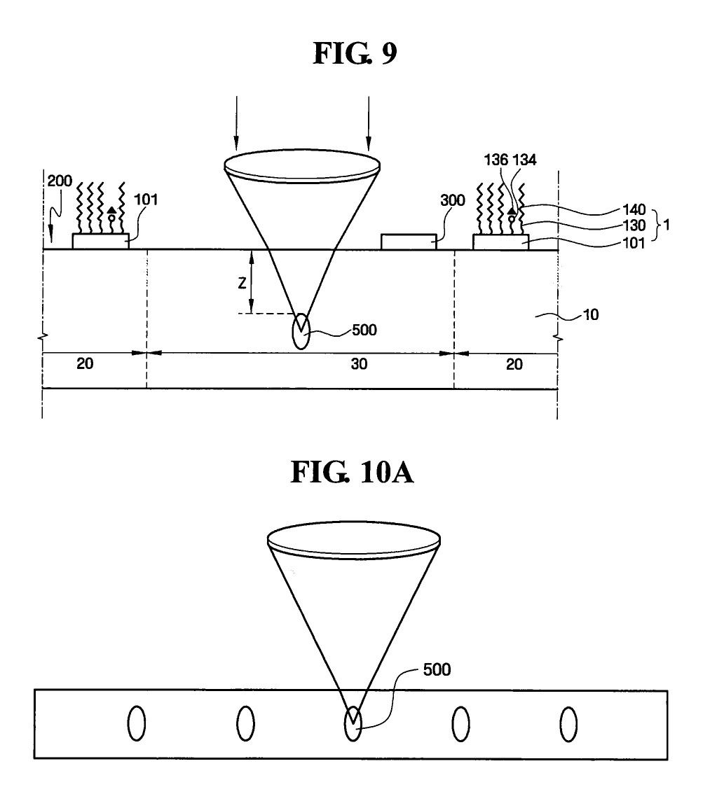

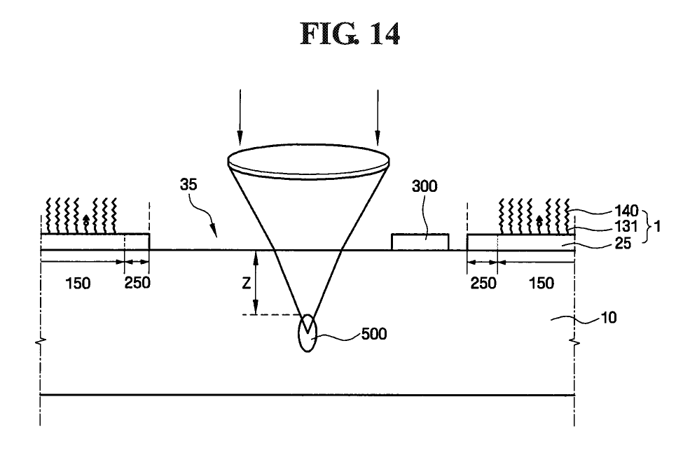

Meanwhile, the non-array region NAR is a region in which the probe cell array 180 is not formed and may expose a part of a surface of the substrate 10. Therefore, for example, the substrate 10 can be cut by a stealth dicing process, so that reliable biochips can be fabricated. This will be described in detail with reference to FIGS. 9 and 14.

The probe cell array 180 includes a plurality of probe cells 1 hybridized to a target sample to detect the target sample. It is defined that each probe cell 1 includes a plurality of probes which can be coupled to a target sample. A probe may be an enzyme, an antibody, a cell, or an oligomer probe.

As used herein, the term “oligomer” is a low molecular weight polymer molecule consisting of two or more covalently bound monomers. Oligomers have a molecular weight of about 1,000 or less but the disclosed technology is not limited thereto. The oligomer may include about 2-500 monomers, and preferably 5-30 monomers. The monomers may be nucleosides, nucleotides, amino acids, peptides, etc. according to the type of probes. In the disclosed technology, previously synthesized oligomer probes may be coupled to active regions, or oligomer probes may be synthesized on active regions by in-situ photolithography.

As used herein, the terms “nucleosides” and “nucleotides” include not only known purine and pyrimidine bases, but also methylated purines or pyrimidines, acylated purines or pyrimidines, etc. Furthermore, the “nucleosides” and “nucleotides” include not only known (deoxy)ribose, but also a modified sugar which contains a substitution of a halogen atom or an aliphatic group for at least one hydroxyl group or is functionalized with ether, amine, or the like.

As used herein, the term “amino acids” are intended to refer to not only naturally occurring, L-, D-, and nonchiral amino acids, but also modified amino acids, amino acid analogs, etc. The term “peptide” refers to compounds produced by an amide bond between the carboxyl group of one amino acid and the amino group of another amino acid.

Accordingly, an oligomer probe may consist of two or more nucleosides, nucleotides, amino acids, or peptides.

The substrate 10 may be a flexible substrate or a rigid substrate. The flexible substrate may be a membrane of nylon or cellulose and a plastic film. The rigid substrate may be a silicon substrate or a transparent glass substrate made of soda-lime glass. Nonspecific binding rarely occurs during hybridization on the silicon or transparent glass substrate. In addition, the silicon or transparent glass substrate is advantageous in that various thin-film fabrication processes and photolithography that have been reliably established and used for the fabrication of semiconductor devices or liquid crystal display (LCD) panels can be used.

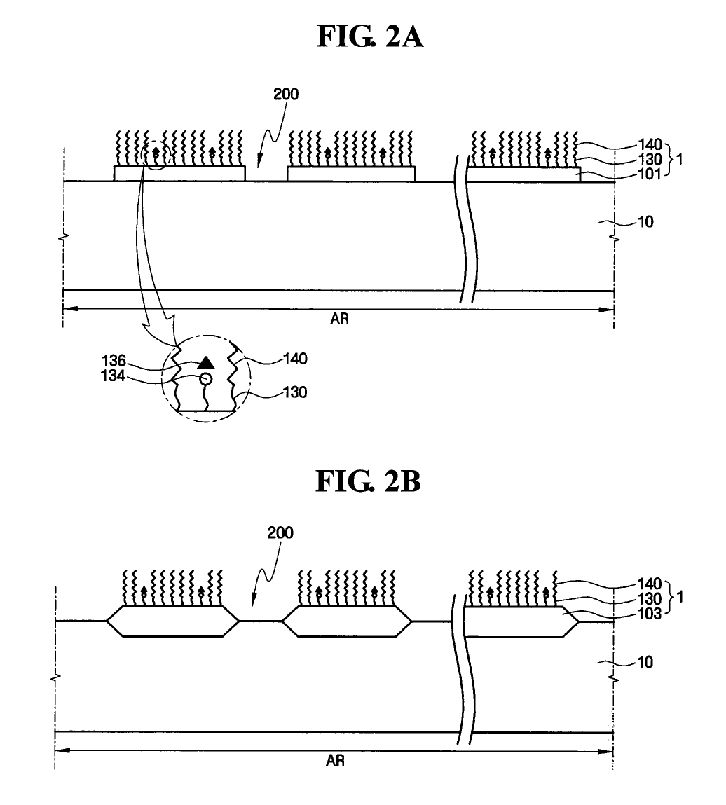

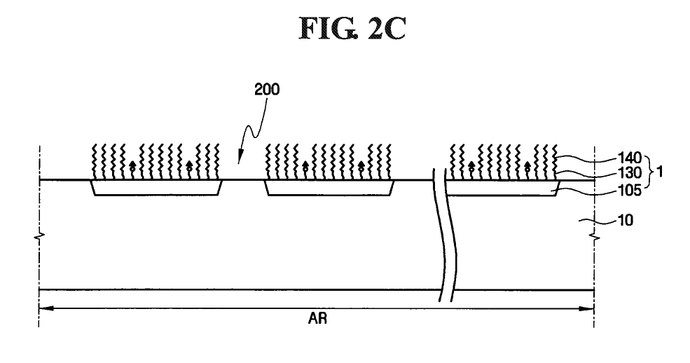

FIGS. 2A through 2C are cross-sectional views of the biochip 50, taken along the line II-II′ and are illustrated to explain a probe cell array in the biochip 50, according to certain embodiments of the disclosed technology.

Referring to FIGS. 2A through 2C, the probe cell array according to certain embodiments of the disclosed technology may include a plurality of activation patterns 101, 103 or 105 which are formed on or in the substrate 10 and a probe cell isolation region 200 which isolates the activation patterns 101, 103 or 105 from each other. The activation patterns 101, 103 or 105 and the probe cell isolation region 200 may be physically separated from each other. In addition, the activation patterns 101, 103 or 105 and the probe cell isolation region 200 may be chemically separated from each other according to the existence or non-existence of a functional group which can be coupled to probes 140 or linkers 130. Here, the activation patterns 101, 103 or 105 may be coupled to the probes 140, forming the probe cells 1.

The functional groups are groups that can be used as starting points for organic synthesis. That is, the functional groups are capable of coupling with (e.g., covalently or non-covalently binding with) the previously synthesized oligomer probes or the monomers (e.g., nucleosides, nucleotides, amino acids, or peptides) for in-situ synthesis of the oligomer probes. The functional groups are not limited to any particular functional groups, provided that they can be coupled to the oligomer probes or the monomers for in-situ synthesis of the oligomer probes. Examples of the functional groups include hydroxyl groups, aldehyde groups, carboxyl groups, amino groups, amide groups, thiol groups, halo groups, and sulfonate groups.

Referring to FIG. 2A, the plurality of activation patterns 101 may be patterns of a film formed on the substrate 10.

Each of the plurality of activation patterns 101 is preferably made of a silicon oxide film such as a PE-TEOS film, a HDP oxide film, a P—SiH₄ oxide film or a thermal oxide film; silicate such as hafnium silicate or zirconium silicate; a metallic oxynitride film such as a silicon nitride film, a silicon oxynitride film, a hafnium oxynitride film or a zirconium oxynitride film; a metal oxide film such as ITO; a metal such as gold, silver, copper or palladium; polyimide; polyamine; or polymers such as polystyrene or polyacrylate.

Referring to FIG. 2B, the plurality of activation patterns 103 may be a LOCal Oxidation of Silicon (LOCOS) film formed in the substrate 10.

Referring to FIG. 2C, the plurality of activation patterns 105 may be trench patterns filling trenches formed in the substrate 10. Here, a material filling the trenches may be, for example, the material that forms the activation patterns 101 illustrated in FIG. 2A.

In the above-described embodiments, the activation patterns 101, 103 or 105 may be coupled to the probes 140. The activation patterns 101, 103 or 105 may be coupled to the probes 140 with the linkers 130 interposed therebetween or they may be directly coupled to the probes 140.

The linkers 130 may include a first linker 130 which facilitates the coupling between an activation pattern 101, 103 or 105 and a probe 140 and a second linker (not shown) which allows the free interaction between the probe 140 and a target sample.

The first linker 130, which may include a functional group, is coupled to the activation pattern 101, 103 or 105 but is not coupled to the probe cell isolation region 200. The functional group is capable of producing siloxane (Si—O) bonds with an Si(OH) group in a case where the Si(OH) group is exposed on a surface of the activation pattern 101, 103 or 105. Examples of the functional group include —Si(OMe)₃, —SiMe(OMe)₂, —SiMeCl₂, —SiMe(OEt)₂, —SiCl₃, —Si(OEt)₃, and the like. The first linker 130 may include a functional group 134 such as a hydroxyl group coupled to carbon (or COH) which is easily coupled to the probe 140 or the second linker. Functional groups 134 may be coupled to probes 140 or second linkers while a functional group 134 that is not coupled to a probe 140 or a second linker may be capped by a capping group 136. The capping group 136 may be coupled to the functional group 134 such as an organic hydroxyl group or an organic amine and deactivate the functional group 134 so that the functional group 134 cannot participate in a chemical reaction. The capping group 136 may be a material that can acetylate the functional group 134 such as a SiOH group or a COH group.

A first end of the second linker is coupled to the second end of a first linker 130 and a second end of the second linker includes a functional group that can be coupled to a probe 140. The functional group may be coupled to a protecting group. Here, when the first linker 130 is long enough to enable the probe 140 to freely interact with a target sample, the second linker may not be used, as illustrated in the drawings.

The term “protecting group” is used to embrace a group which blocks a bond at a coupling site from participating in a chemical reaction and the term “deprotection” is used to mean that a protecting group is cleaved from the coupling site to participate in a chemical reaction. That is, since the protecting group may be either acidlabile or photolabile, the functional group can be deprotected by acid or light. For example, the photolabile protecting group may be selected among a variety of positive photolabile groups containing nitro aromatic compounds such as o-nitrobenzyl derivatives or benzyl sulfonyl group. Examples of the photolabile protecting group include 6-nitroveratryloxycarbonyl group (NVOC), 2-nitrobenzyloxycarbonyl group (NBOC), α,α-dimethyl-dimethoxybenzyloxycarbonyl (DDZ), and the like.

The probe cell isolation region 200 separates the activation patterns 101, 103 or 105 from one another and may not include a functional group coupled to the probes 140.

As illustrated in FIGS. 2A through 2C, a surface of the probe cell isolation region 200 may be an exposed surface of the substrate 10. For example, when the substrate 10 is a silicon substrate or a transparent glass substrate, the surface of the probe cell isolation region 200 may be an exposed surface of the silicon substrate and the transparent glass substrate. The probe cell isolation region 200 may not be physically separated from the non-array region NAR.

Alternatively, although not shown, a coupling blocking film may be further formed between the activation patterns 101, 103 or 105. In this case, the surface of the probe cell isolation region 200 is a surface of the coupling blocking film and may be physically separated from the non-array region NAR. A functional group that can be coupled to a probe such as an oligomer probe may not exist on the surface of the coupling blocking film. For example, the coupling blocking film may be a fluoride film such as a fluorosilane film including a fluoride group, a silicide film, or an epitaxial film such as a Si or SiGe film.

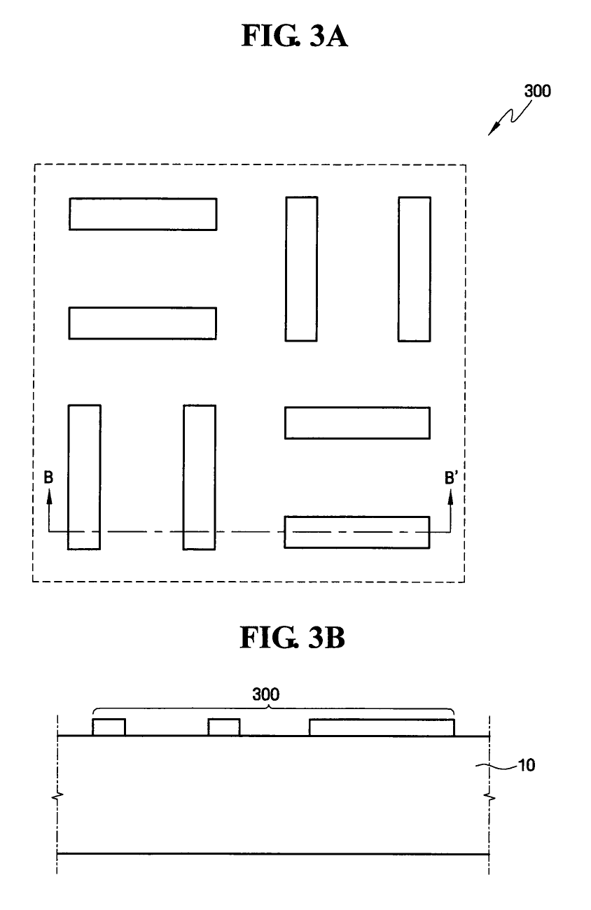

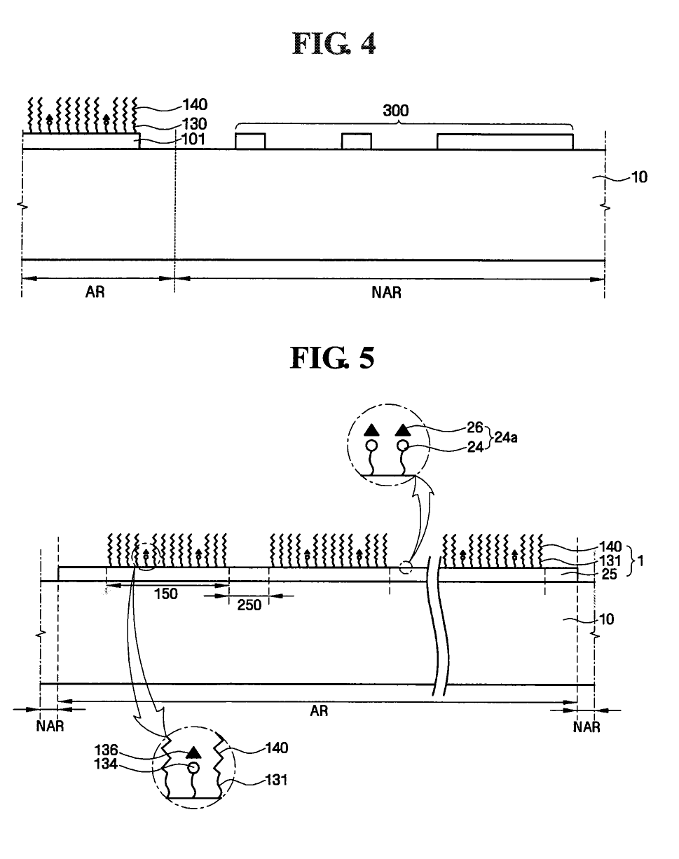

FIGS. 3A, 3B, and 4 illustrate an align key in a biochip according to certain embodiments of the disclosed technology. FIG. 3A is a top view of an align key 300. FIG. 3B is a cross-sectional view of the align key 300 taken along the line B-B′. FIG. 4 is a cross-sectional view of the align key 300 taken along the line IV-IV′ illustrated in FIG. 1.

Referring to FIG. 1 and FIGS. 3A and 3B, the align key 300 may be formed on or in the substrate 10 in the non-array region NAR. The align key 300 may be used as an align reference during consecutive biochip fabrication processes and detection processes using a biochip. For example, the align key 300 may be used as the align reference while individual biochips are packaged or during a scanning process in which a hybrid site is detected after a biochip is hybridized with a target sample.

The align key 300 needs to be optically distinguished from the substrate 10 and may be formed in various patterns such as L-shaped patterns and cross-shaped patterns for the distinguishment. The align key 300 may be formed using metal such as aluminum or the same material as that forming the activation patterns 101, 103 or 105. For example, the align key 300 and the activation patterns 101 may be formed in a membrane form such as a silicon oxide film. The align key 300 and the activation patterns 101 may have the same height from the surface of the substrate 10. Although not shown, an align key may not be formed on a biochip in other embodiments of the disclosed technology.

FIG. 5 is a cross-sectional view of the probe cell array 180 of FIG. 1 taken long the line V-V′ and illustrates the probe cell array 180 according to other embodiments of the disclosed technology. Referring to FIGS. 1 and 5, a biochip according to the current embodiment of the disclosed technology has a substantially similar layout to that according to above-described embodiments of the disclosed technology, with the exception that probe cells 1 are not physically separated from one another in the probe cell array 180.

Referring to FIG. 5, the probe cell array 180 may include an activated probe cell area 150 in which the probes 140 are coupled to an activation layer 25 formed on the substrate 10 and a deactivated probe cell area 250 in which the activation layer 25 is not coupled to any probes. The surface of the substrate 10 may be exposed in at least a part of the non-array region NAR while the surface of the substrate 10 is not exposed in the array region AR. When the align key 300 is not formed in the non-array region NAR, the surface of the substrate 10 may be exposed throughout the non-array region NAR.

The surface of the substrate 10 is exposed in at least a part of the non-array region NAR, and therefore, for example, the substrate 10 can be cut using the stealth dicing process. As a result, reliable biochips can be fabricated. This will be described in detail with reference to FIGS. 9 and 14 later.

The activation layer 25 may include a deactivated functional group 24a having a deactivating cap. Specifically, there is a functional group 24 that is capable of being coupled to a probe 140 on a surface of the activation layer 25. The functional group 24 is coupled to a protecting group 26 so that the functional group 24 can remain deactivated until the protecting group 26 is taken off. For example, the activation layer 25 may be formed by allowing an organic silane layer (e.g., an amino silane layer or an epoxy silane layer), which includes the functional group 24 that can be organically coupled to a linker 131 or the probe 140, to react with the protecting group 26.

The activated probe cell area 150 may be coupled to probes 140, forming the probe cell 1. The activated probe cell area 150 can be coupled to the probes 140 directly or with linkers 131 interposed therebetween. The linkers 131 may enable free interaction with a target sample.

In the deactivated probe cell area 250, the functional group 24 may be deactivated by the protecting group 26. Accordingly, the deactivated probe cell area 250 may not be coupled to the probes 140 or the linkers 131.

A method of fabricating a biochip according to certain embodiments of the disclosed technology will be described below with reference to FIGS. 1 through 4 and 6 through 9.

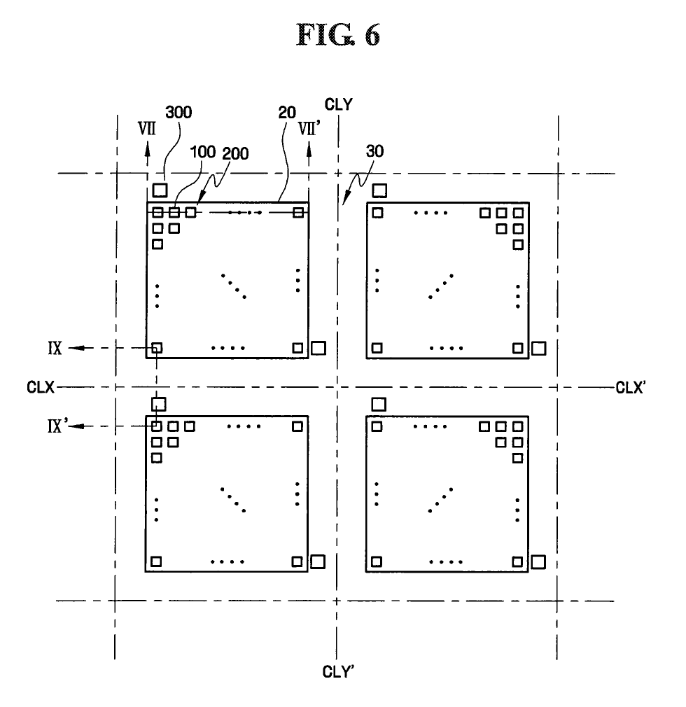

FIG. 6 is a top view of a substrate on which activation patterns 100 are formed using a method of fabricating a biochip according to certain embodiments of the disclosed technology. Referring to FIG. 6, a plurality of activation patterns 100 isolated from one another by the probe cell isolation region 200 are formed on or in the substrate 10 in each of a plurality of first areas 20 which are isolated from one another by a second area 30. Each of the first areas 20 is an area in which the probe cell array 180 including the activation patterns 100 and the probe cell isolation region 200 is formed. The second area 30 may include a part at which the substrate 10 is cut and at least a part of the surface of the substrate in the second area 30 may be exposed.

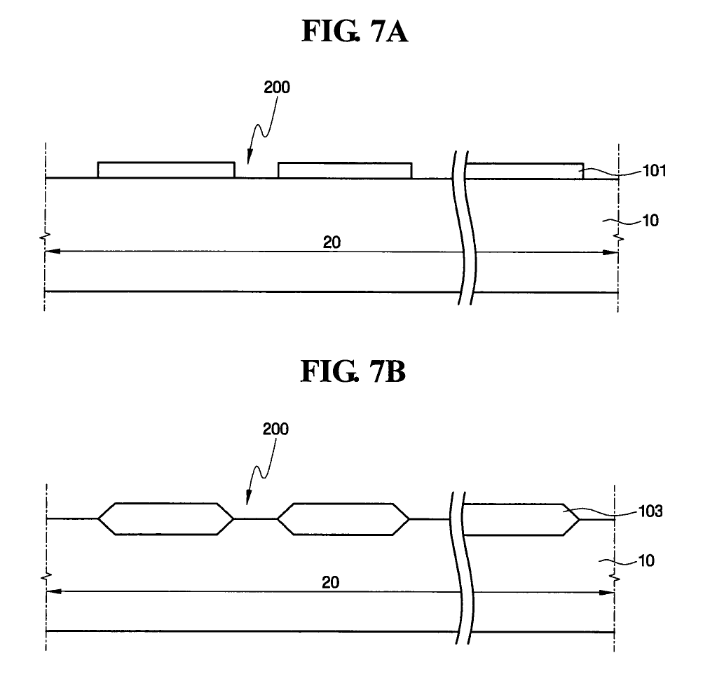

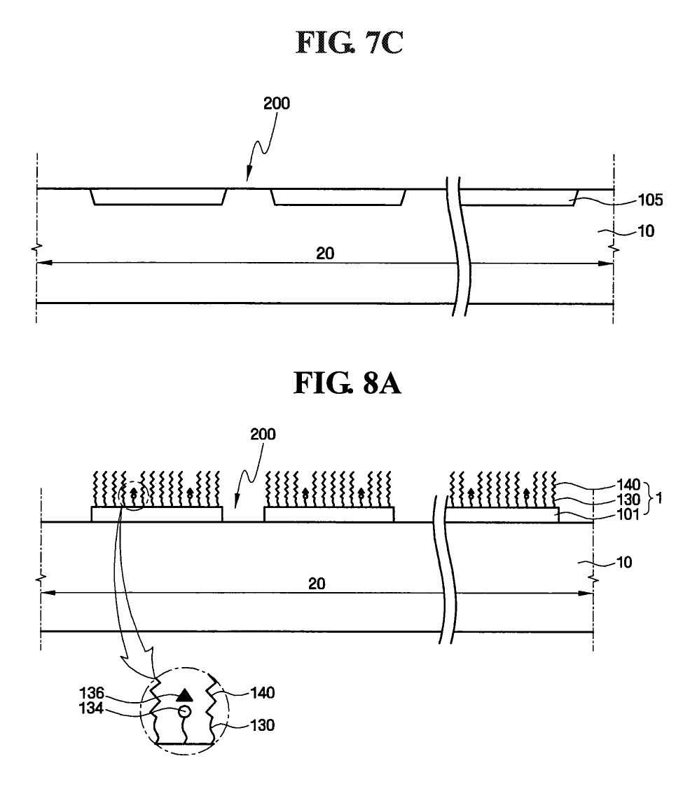

FIGS. 7A through 7C are cross-sectional views taken along the line VII-VII′ shown in FIG. 6, an illustrate activation patterns formed in the method of fabricating a biochip according to certain embodiments of the disclosed technology.

Referring to FIGS. 7A through 7C, the activation patterns 101, 103 or 105 according to different embodiments of the disclosed technology may be physically separated from one another by the probe cell isolation region 200.

Referring to FIG. 7A, the activation patterns 101 may be formed in a membrane form on the substrate 10 according to an embodiment of the disclosed technology.

The membrane, for example, may be formed by forming and patterning an activation pattern forming film. The activation pattern forming film may be formed using the same material as the activation patterns 100. For example, the activation pattern forming film may be made of a silicon oxide film such as a PE-TEOS film, a HDP oxide film, a P—SiH₄ oxide film or a thermal oxide film; silicate such as hafnium silicate or zirconium silicate; a metallic oxynitride film such as a silicon nitride film, a silicon oxynitride film, a hafnium oxynitride film or a zirconium oxynitride film; a metal oxide film such as ITO; a metal such as gold, silver, copper or palladium; polyimide; polyamine; or polymers such as polystyrene or polyacrylate. The activation pattern forming film may be formed on the substrate 10 using a deposition method that has been stably applied in a semiconductor or LCD fabrication process, e.g., CVD (Chemical Vapor Deposition), SACVD (Sub-Atmospheric CVD), LPCVD (Low Pressure CVD), PECVD (Plasma Enhanced CVD), sputtering, or spin-coating.

The patterning of the activation pattern forming film may include forming a photoresist pattern on the activation pattern forming film, etching the activation pattern forming film using the photoresist pattern as an etching mask, and removing the photoresist pattern. The photoresist pattern may be formed by forming a photoresist layer on the activation pattern forming film and performing exposure and development using a mask.

Referring to FIG. 7B, the activation patterns 103 may be formed by forming a LOCOS film in the substrate 10 according to another embodiment of the disclosed technology. The LOCOS film, for example, may be formed by forming an oxidation preventing pattern on the substrate 10 and oxidizing a portion of the substrate 10 exposed by the oxidation preventing pattern. The oxidation preventing pattern may be a nitride film or a stack layer of oxide and nitride.

Referring to FIG. 7C, the activation patterns 105 may be formed in trench patterns filling trenches formed in the substrate 10 according to another embodiment of the disclosed technology. For example, the activation patterns 105 may be formed by forming trenches in the substrate 10, filling the trenches with the above-described activation pattern forming material, and performing planarization using chemical mechanical polishing (CMP) or etch back.

Referring to FIGS. 7A through 7C, the surface of the probe cell isolation region 200 may be the exposed surface of the substrate 10 such as the surface of the substrate 10 in the second area 30. For example, when the substrate 10 is a silicon substrate or a transparent glass substrate, the surface of the probe cell isolation region 200 may be the surface of the silicon or glass substrate. The probe cell isolation region 200 may not be physically separated from the substrate 10 in the second area 30.

Although not shown, a coupling blocking film may be further formed between the activation patterns 101, 103 or 105 according to certain embodiments of the disclosed technology. In this case, the surface of the probe cell isolation region 200 may be a surface of the coupling blocking film and the probe cell isolation region 200 may be physically separated from the substrate 10 in the second area 30.

Referring to FIGS. 3A, 3B, and 6, the align key 300 may be formed on or in the substrate 10 in the second area 30. When the align key 300 is formed, the entire surface of the substrate 10 in the second area 30 except for a portion where the align key 300 is formed may be exposed.

The align key 300 may be used as an align reference during consecutive biochip fabrication processes and scanning processes. For example, the align key 300 can be used to align the substrate 10 with a mask or an exposure device during photolithography or to align the substrate 10 during a dicing process of cutting the substrate 10 into individual biochips. In addition, the align key 300 may be used as the align reference during packaging of the individual biochips and detecting processes such as the scanning processes after hybridization.

The align key 300 needs to be optically distinguished from the substrate 10 and may be formed in various patterns such as L-shaped patterns and cross-shaped patterns. The align key 300 may be formed using, for example, metal such as aluminum or the same material as that of the activation patterns 101, 103 or 105. For example, when the align key 300 is formed in a membrane form such as the activation patterns 101, the activation patterns 101 and the align key 300 may be simultaneously formed. In detail, when an activation pattern forming film formed on the substrate 10 is patterned, the align key 300 and the activation patterns 101 are simultaneously formed. The activation patterns 101 and the align key 300 may have the same height from the surface of the substrate 10. Although not shown, the activation patterns 101 and the align key 300 may be simultaneously formed while a LOCOS film is formed using an oxidation preventing pattern according to other embodiments of the disclosed technology.

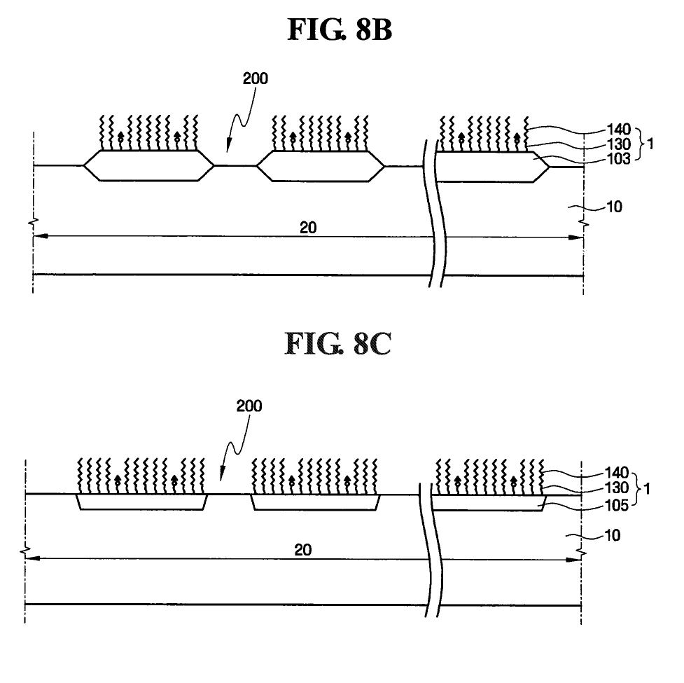

FIGS. 8A through 8C are diagrams for explaining a probe cell array in a method of fabricating a biochip according to different embodiments of the disclosed technology. FIGS. 8A through 8C show states in which the probes 140 are coupled to the activation patterns 101, 103, and 105 illustrated in FIGS. 7A through 7C, respectively.

Referring to FIGS. 8A through 8C, different types of the probes 140 may be coupled to the different activation patterns 101, 103, and 105, respectively. Here, the probes 140 may be oligomer probes. The activation patterns 101, 103, and 105 may be coupled to the probes 140 directly or with the linkers 130 interposed therebetween.

The linkers 130 may include a first linker 130 which facilitates the coupling between an activation pattern 101, 103 or 105 and a probe 140 and a second linker (not shown) which allows the free interaction between the probe 140 and a target sample. Here, when the first linker 130 is long enough to enable the probe 140 to freely interact with a target sample, the second linker may not be used, as illustrated in the drawings. Coupling the linker 130 and the probe 140 may be coupling between the linker 130 and a probe such as a pre-compounded oligomer probe or coupling using in-situ synthesis of a monomer for a probe.

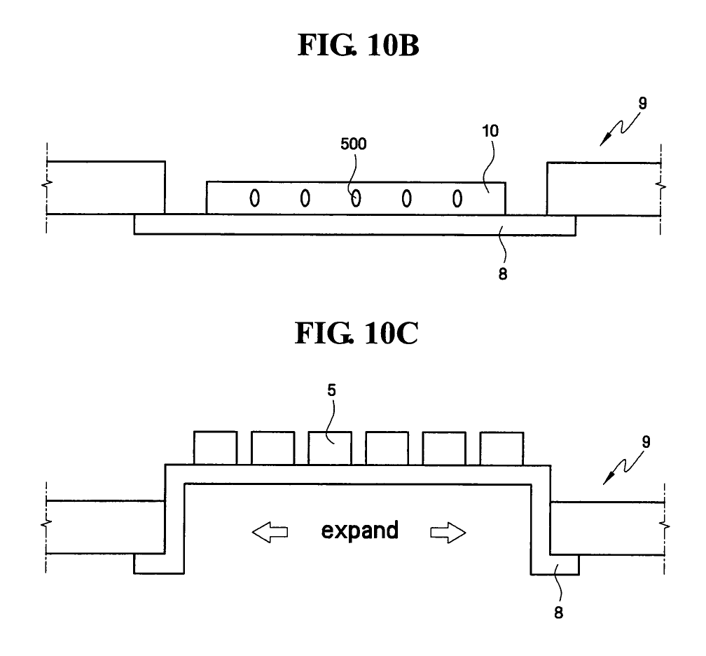

FIG. 9 is a cross-sectional view of the substrate taken along the line IX-IX′ illustrated in FIG. 6. FIG. 9 illustrates a stealth dicing process in a method of fabricating a biochip according to certain embodiments of the disclosed technology. FIGS. 10A through 10C are diagrams for explaining an example of the stealth dicing process in the method of fabricating a biochip according to certain embodiments of the disclosed technology.

Referring to FIGS. 6 and 9, the substrate 10 is cut along the second area 30 so that multiple biochips are formed. The substrate 10 in the second area 30 may be cut along the line CLX-CLX′ and the line CLY-CLY′. The substrate 10 in the second area 30 whose surface is exposed may be cut using, for example, blade dicing, laser dicing, or stealth dicing. In the current embodiment of the disclosed technology, since the surface of the substrate 10 in the second area 30 is exposed, the substrate 10 may be cut using the stealth dicing.

The stealth dicing includes focusing and radiating a laser beam (e.g., an infrared (IR) laser beam) on an inside of the substrate 10. Unlike other laser dicing, in stealth dicing, since the laser beam is radiated on the inside of the substrate 10 to form a modified region 500, the surface of the substrate 10 does not melt. In addition, unlike blade dicing, since physical force is not applied to the surface of the substrate 10 in the stealth dicing, chipping does not occur. Accordingly, the substrate 10 can be cleanly cut without chipping, vibration, and thermal degeneration.

When an oxide layer is stacked on the substrate 10, the laser beam may not be effectively radiated on the inside of the substrate 10 in the stealth dicing. However, as described above, since the surface of the substrate 10 in the second area 30 is exposed in the current embodiment of the disclosed technology, the laser beam can be directly incident to the exposed surface of the substrate 10 and effectively form the modified region 500 inside the substrate 10. As a result, the substrate 10 can be effectively cut using the stealth dicing while the probes 140 are prevented from being damaged by vibration or thermal degeneration.

Referring to FIGS. 10A through 10C, dicing may be performed without attaching and removing a protecting film for preventing the damage of the probes 140 according to certain embodiments of the disclosed technology. In detail, modified regions 500 can be formed within the substrate 10 without attaching the protecting film for preventing the damage of the probes 140. The substrate 10 having the modified regions 500 is placed on, for example, a jig 9 including an adhesive film 8, where the jig 9 is expanded (as shown in FIG. 10B) to divide the substrate 10 into a plurality of chips 5 (as shown in FIG. 10C). The adhesive film 8 may be a high molecular substance having flexibility. Since the substrate 10 can be cut without attaching and removing a special protecting film, process throughput can be increased.

Referring to FIG. 9, the modified region 500 may be formed at a predetermined depth Z from the surface of the substrate 10 according to certain embodiments of the disclosed technology. For example, the modified region 500 may be formed at a depth of at least 5 μm so that a thermally degenerated layer cannot be formed on the surface of the substrate 10. Although not shown, at least two modified regions may be formed in a vertical direction with respect to the substrate 10 according to other embodiments of the disclosed technology. For instance, when the substrate 10 is thick, two of more modified regions may be formed in the vertical direction in order to effectively dice the substrate 10.

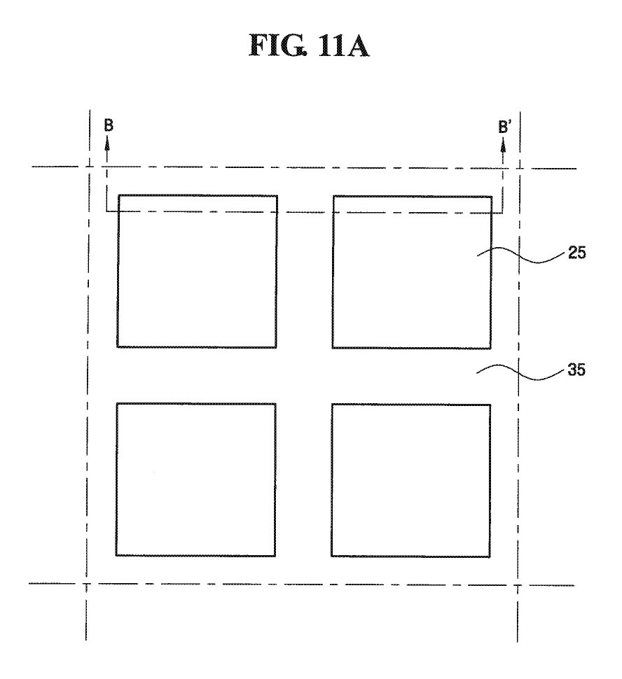

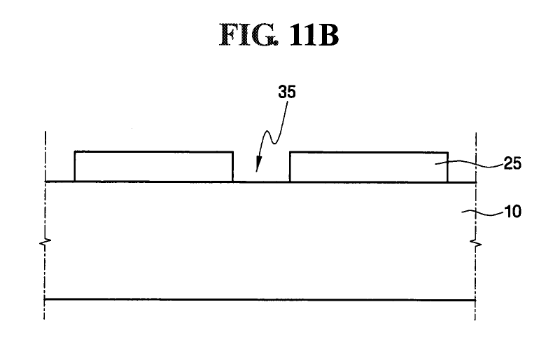

FIGS. 11A through 14 illustrate a method of fabricating a biochip according to other embodiments of the disclosed technology.

FIGS. 11A and 11B illustrate the activation layer 25 in a method of fabricating a biochip according to certain embodiments of the disclosed technology. FIG. 11A is a top view of an intermediate structure having the activation layer 25. FIG. 11B is a cross-sectional view of the intermediate structure taken along the line B-B′.

Referring to FIGS. 11A and 11B, a plurality of activation layers 25 are formed on the substrate 10. The activation layers 25 are separated from one another by an isolation region 35. The isolation region 35 may expose at least part of the surface of the substrate 10. The activation layers 25 may be formed in substantially the same area of the substrate 10 as the first area 20 of FIG. 6 in which a probe cell array is formed.

The activation layers 25 may be formed by forming an activation layer material film on the substrate 10 and patterning the activation layer material film. The activation layer material film may be formed using a material including a functional group having a deactivating cap, as described above. For example, the activation layer material film may be formed by forming an organic silane layer (e.g., an amino silane layer or an epoxy silane layer), which has a functional group that can be organically coupled to a linker or a probe, on the substrate 10 and coupling the functional group on a surface of the organic silane layer to a protecting group.

The patterning of the activation layer material film may include forming a photoresist pattern on the activation layer material film, etching the activation layer material film using the photoresist pattern as an etching mask, and removing the photoresist pattern. The photoresist pattern may be formed by forming a photoresist layer on the activation layer material film and performing exposure and development using a mask.

According to certain embodiments of the disclosed technology, the align key 300 may be formed on or in the substrate 10 in the isolation region 35. The align key 300 may be formed using metal such as aluminum or the same material as that forming the activation layers 25. For example, when the align key 300 is formed using a metal such as aluminum, the align key 300 may be formed before the activation layers 25 are formed.

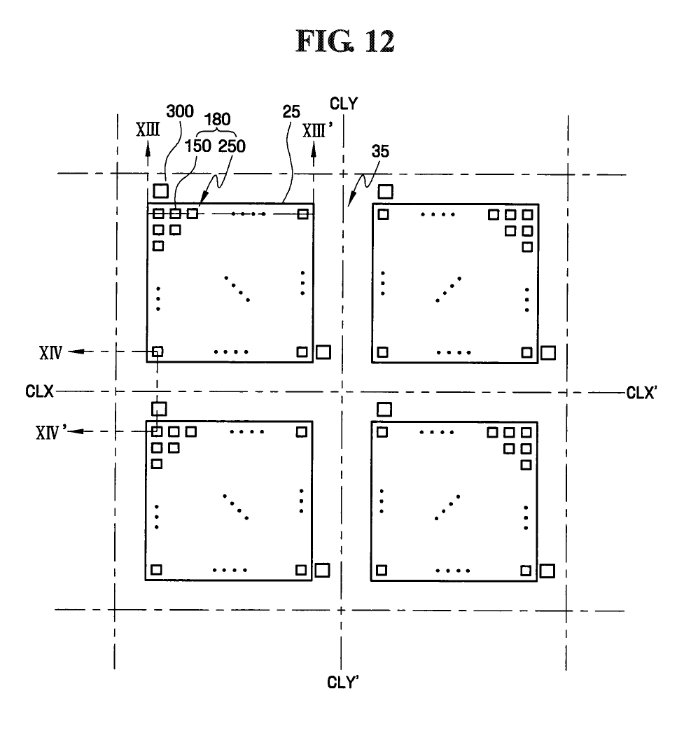

FIG. 12 is a top view of an intermediate structure in which the probe cell array 180 is formed according to a method of fabricating a biochip according to other embodiments of the disclosed technology. Referring to FIG. 12, the probe cell array 180 is formed on each of the activation layers 25. The probe cell array 180 may include, for example, the activated probe cell area 150 and the deactivated probe cell area 250. The activated probe cell area 150 may be coupled to a probe to form a probe cell.

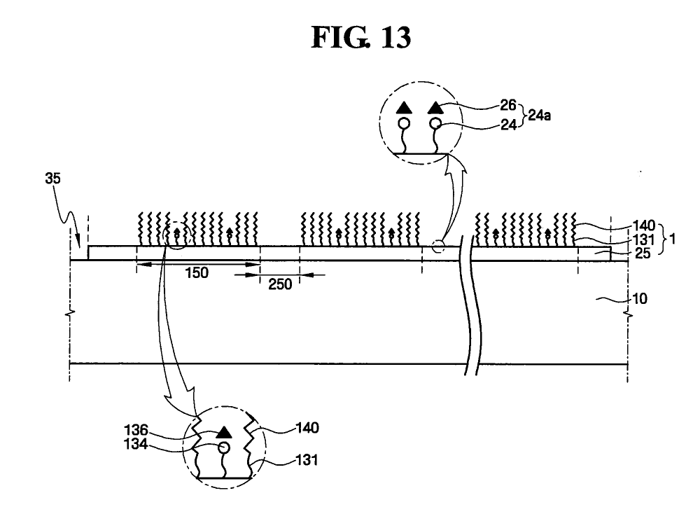

FIG. 13 is a cross-sectional view of the intermediate structure taken along the line XIII-XIII′ illustrated in FIG. 12 and illustrates the probe cell array 180 formed using a method of fabricating a biochip according to other embodiments of the disclosed technology. Referring to FIG. 13, forming the probe cell array 180 may include forming a probe cell 1 by partially activating the deactivated functional group 24a having a deactivating cap on the activation layer 25 and coupling the activated functional group 24 to a probe 140. Here, the activated functional group 24 may be coupled to the probe 140 with the linker 131 interposed therebetween or they may be coupled directly. For example, the linker 131 may allow free interaction with a target sample.

Partially activating the deactivated functional group 24a having the deactivating cap on the activation layer 25 may performed by, for example, partially removing the protecting group 26 coupled to the functional group 24 using an acid or light. For example, light may be partially radiated on the activation layer 25 using a mask so that the activated probe cell area 150 having the activated functional group 24 is separated from the deactivated probe cell area 250 having the deactivated functional group 24a. The activated probe cell area 150 and the deactivated probe cell area 250 may not be separated physically but may be separated chemically.

The activated functional group 24 may be coupled to the probe 140 by way of coupling the activated functional group 24 to a probe such as a precompounded oligomer probe or coupling using in-situ synthesis of a monomer for a probe.

Although not shown, according to other embodiments of the disclosed technology, the probe cell array 180 may be formed on the activation layer 25 using a bead coupled to a probe. For example, a plurality of probes may be coupled to a bead and then the bead may be bonded to the activation layer 25.

FIG. 14 is a cross-sectional view of the intermediate structure taken along the line XIV-XIV′ illustrated in FIG. 12 and illustrates stealth dicing in certain embodiments of the disclosed technology. Referring to FIGS. 12 and 14, the substrate 10 is cut along the isolation region 35 to form a plurality of biochips. The substrate 10 in the isolation region 35 may be cut along the line CLX-CLX′ and the line CLY-CLY′. The substrate 10 in the isolation region 35 whose surface is exposed may be cut using, for example, blade dicing, laser dicing, or stealth dicing. As described above, in certain embodiments of the disclosed technology, since the surface of the substrate 10 in the isolation region 35 is exposed, the substrate 10 can be cleanly cut without chipping, vibration, and thermal degeneration.

The modified region 500 may be formed at the predetermined depth Z from the surface of the substrate 10 according to certain embodiments of the disclosed technology. For example, the modified region 500 may be formed at a depth of at least 5 mm so that a thermally degenerated layer cannot be formed on the surface of the substrate 10. Although not shown, at least two modified regions may be formed in a vertical direction according to other embodiments of the disclosed technology. For instance, when the substrate 10 is thick, two or more modified regions may be formed in the vertical direction in order to effectively dice the substrate 10.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims to indicate the scope of the invention.

What is claimed is:

1. A method of fabricating a biochip comprising:
providing a substrate including a plurality of first areas separated from each other by a second area;
forming a plurality of activation patterns on each of the first areas;
coupling a plurality of probes to each of the activation patterns; and
cutting the substrate along the second area to form a plurality of chips.

2. The method of claim 1, wherein the cutting of the substrate comprises focusing and radiating a laser beam on an inside of the substrate and forming a modified region.

3. The method of claim 2, wherein the modified region is formed at least about 5 μm apart from a surface of the substrate.

4. The method of claim 2, wherein at least two modified regions are formed in a vertical direction with respect to the substrate.

5. The method of claim 1, wherein the forming of the plurality of activation patterns comprises exposing a surface of the substrate in the second area.

6. The method of claim 1, wherein the forming of the plurality of activation patterns comprises forming a probe cell isolation region which isolates each of the plurality of activation patterns from each other.

7. The method of claim 6, wherein the substrate is a silicon substrate or a transparent glass substrate and a surface of the substrate in the probe cell isolation region is exposed.

8. The method of claim 1, the forming of the plurality of activation patterns comprises patterning a membrane formed on the substrate, forming a LOCal Oxidation of Silicon (LOCOS) film by partially oxidizing the substrate, or forming trench pattern active portions filling trenches formed in the substrate.

9. A method of fabricating a biochip comprising:
providing a substrate including a plurality of first areas separated from each other by a second area;
forming an activation layer on each of the first areas;
coupling a plurality of probes to the activation layer; and
cutting the substrate along the second area to form a plurality of chips.

10. The method of claim 9, wherein the cutting of the substrate comprises focusing and radiating a laser beam on an inside of the substrate and forming a modified region.

11. The method of claim 10, wherein the modified region is formed at least about 5 μm apart from a surface of the substrate.

12. The method of claim 10, wherein at least two modified regions are formed in a vertical direction with respect to the substrate.

13. The method of claim 9, wherein the forming of the activation layer comprises exposing a surface of the substrate in the second area.

14. The method of claim 9, wherein the forming of the activation layer comprises forming the activation layer on an entire surface of the substrate on each of the first areas.

15. The method of claim 1, further comprising forming a blocking film between each of the activation patterns.

16. The method of claim 9, wherein the biochip comprises an array region and a non-array region surrounding the array region.

17. The method of claim 16, further comprising forming a probe cell array formed on or in the substrate in the array region.

18. The method of claim 17, wherein a surface of the substrate is at least partially exposed in the non-array region.

19. The method of claim 17, further comprising forming a probe cell by at least partially activating a deactivated functional group.

20. The method of claim 9, further comprising interposing one of a plurality of linkers between each of a corresponding one of the plurality of probes and the activation layer.
